(19) United States
(12) Patent Application Publication
(10) Pub. No.: US 2020/0333271 A1
(43) Pub. Date: Oct. 22, 2020

(54) METHOD FOR CONTROLLING A UNIT OF A PARTICLE BEAM DEVICE AND PARTICLE BEAM DEVICE FOR CARRYING OUT THE METHOD

(71) Applicant: Carl Zeiss Microscopy GmbH, Jena (DE)

(72) Inventors: Christian Hendrich, Westhausen (DE); Martin Kienle, Ellwangen (DE); Josef Biberger, Wildenberg (DE); Michal Postolski, Barlinek (PL)

(73) Assignee: Carl Zeiss Microscopy GmbH, Jena (DE)

(21) Appl. No.: 16/866,815

(22) Filed: May 5, 2020

(30) Foreign Application Priority Data
May 6, 2019 (DE) 102019111727.5

(51) Int. Cl. G01N 23/2251; H01J 37/285

(52) U.S. Cl. CPC G01N 23/2251; H01J 37/285

(57) ABSTRACT

The invention described herein relates to a method for controlling a unit of a particle beam device for imaging, analyzing and/or processing an object. Moreover, the invention described herein relates to a particle beam device for carrying out the method. The method comprises identifying at least one part of at least one hand (134) of a user or at least one complete hand (134) of a user by means of an identification unit (130, 131), wherein the identification unit (130, 131) is at least one of: (i) a first camera unit (130), (ii) a first touchless motion sensor (131) or (iii) a first wireless motion sensor; tracking an absolute movement and/or a relative movement of the at least one part of the at least one hand (134) of the user or the at least one complete hand (134) of the user by means of a tracking unit (130, 131), wherein the tracking unit (130, 131) is at least one of: (i) a second camera unit (130), (ii) a second touchless motion sensor (131) or (iii) a second wireless motion sensor; transforming the movement of the at least one part of the at least one hand (134) of the user or the at least one complete hand (134) of the user into a command for a control of the unit of the particle beam device by means of a transformation unit (128); and providing the control of the unit of the particle beam device by means of the command, wherein the command is used as an input in a control unit for controlling the unit of the particle beam device.

The invention described herein relates to a method for controlling a unit of a particle beam device for imaging, analyzing and/or processing an object. Moreover, the invention described herein relates to a particle beam device for carrying out the method. For example, the particle beam device is an electron beam device and/or or an ion beam device. Moreover, the unit of the particle beam device is, for example, a manipulator for an object, a detector, a gas injection device, an aperture unit and/or an object stage for arranging an object in an object chamber of the particle beam device.

Electron beam devices, in particular a scanning electron microscope (also referred to as SEM below) and/or a transmission electron microscope (also referred to as TEM below), are used to examine objects (also referred to as samples) in order to obtain knowledge in respect of the properties and behavior of the objects under certain conditions.

In an SEM, an electron beam (also referred to as primary electron beam below) is generated using a beam generator and focused on an object to be examined using a beam guiding system. An objective lens is used for focusing purposes. The primary electron beam is guided over a surface of the object to be examined by way of a deflection device. This is also referred to as scanning. The area scanned by the primary electron beam is also referred to as scanning region. In this area, the electrons of the primary electron beam interact with the object to be examined. Interaction particles and/or interaction radiation result as a consequence of the interaction. By way of example, the interaction particles are electrons. In particular, electrons are emitted by the object—the so-called secondary electrons—and electrons of the primary electron beam are scattered back—the so-called backscattered electrons. The interaction particles form the so-called secondary particle beam and are detected by at least one particle detector. The particle detector generates detection signals which are used to generate an image of the object. An image of the object to be examined is thus obtained. By way of example, the interaction radiation is X-ray radiation or cathodoluminescence. At least one radiation detector is used to detect the interaction radiation. Additionally or alternatively, electrons of the primary electron beam are used to ablate or modify the object.

In the case of a TEM, a primary electron beam is likewise generated using a beam generator and directed onto an object to be examined using a beam guiding system. The primary electron beam passes through the object to be examined. When the primary electron beam passes through the object to be examined, the electrons of the primary electron beam interact with the material of the object to be examined. The electrons passing through the object to be examined or the electrons emitted by the object are imaged onto a luminescent screen or onto a detector—for example in the form of a camera—by a system comprising an objective. By way of example, the aforementioned system additionally comprises a projection lens. Imaging may also take place in the scanning mode of a TEM. Such a TEM is often referred to as STEM. Additionally, provision may be made for detecting particles scattered back at the object to be examined and/or secondary particles emitted by the object to be examined using at least one further detector in order to image the object to be examined. Additionally or alternatively, in a TEM or STEM, electrons of the primary electron beam are used to ablate or modify the object.

Combining the functions of an STEM and an SEM in a single particle beam device is known. It is therefore possible to carry out examinations of objects with an SEM function and/or with an STEM function using this particle beam device.

Moreover, a particle beam device in the form of an ion beam column is known. Ions used for processing an object are generated using an ion beam generator arranged in the ion beam column. By way of example, material of the object is ablated or material is applied onto the object during the processing. The ions are additionally or alternatively used for imaging by generating interaction particles and/or interaction radiation generated by an interaction of the ions with the object when impinging the object, wherein the interaction particles are, for example, secondary electrons, and wherein the interaction radiation is, for example, X-rays.

Furthermore, the prior art has disclosed the practice of analyzing and/or processing an object in a particle beam device using, on one hand, electrons and, on the other hand, ions. By way of example, an electron beam column having the function of an SEM is arranged at the particle beam device. Additionally, an ion beam column, as explained above, is arranged at the particle beam device. The electron beam column with the SEM function serves, in particular, for examining further the processed or unprocessed object, but also for processing the object. The aforementioned particle beam device is often used for preparing an object to be examined with a TEM. For example, an object in the form of a part of bulk material is cut out of the bulk material using the ion beam of the ion beam column. After having been cut out of the bulk material, the cut out part of the bulk material is arranged at a micromanipulator used for lifting the cut out part of the bulk material out of the bulk material and/or for arranging the cut out part of the bulk material at a sample holder, for example a TEM grid. For example, the cut out part of the bulk material is attached to a needle being arranged at one end of the micromanipulator. Alternatively, the cut out part of the bulk material may be arranged between a first gripper unit and a second gripper unit, wherein the first gripper unit and the second gripper unit may be arranged at the one end of the micromanipulator. The sample holder may be introduced into an object chamber of the TEM or any other examination device for further analysis of the cut out part of the bulk material.

It is known to move the micromanipulator in a three-dimensional space using a joystick or button control unit which interacts with a drive unit for moving the micromanipulator. A user may use the joystick or button control unit for moving the micromanipulator, for example, in three directions arranged perpendicular to one another, namely in an x-direction, in a y-direction and in a z-direction. Additionally, the micromanipulator may be rotated using the joystick or button control unit about a first micromanipulator axis of rotation and about a second micromanipulator axis of rotation which is, for example, arranged perpendicular to the first micromanipulator axis of rotation.

The known ways of controlling the movement of the micromanipulator might cause problems. For example, a user might confuse the axes of direction or axes of rotation of the movement of the micromanipulator such that the user moves the micromanipulator into a direction different from the direction of movement of the micromanipulator actually desired. Moreover, it is sometimes difficult to control the velocity and/or the acceleration of the movement of the micromanipulator using the known ways of controlling the movement. In particular, it happens sometimes that a user moves the micromanipulator too fast and, therefore, the micromanipulator might collide with further units of the particle beam device, thereby destroying the cut out part of the bulk material, the micromanipulator itself and/or further parts of the particle beam device. Furthermore, it is sometimes difficult for the user to control several axes of direction and axes of rotation at once and to provide for compensation of the movement of the micromanipulator, which might be necessary since the user does not use the same coordinate system as the micromanipulator.

It is therefore desirable to provide a method and a particle beam device for carrying out the method, by means of which a control of a unit of a particle beam device is provided, in particular for a micromanipulator, an object stage, a gas injection device, an electrical testing probe, a mechanical testing probe or an optical testing probe.

According to the invention, this object is reached by a method according to claim 1. A further method according to the invention is given by the features of claim 7. A computer program product comprising a program code for controlling a particle beam device is given by the features of claim 19. A particle beam device for carrying out the method is given by claim 20. Further features of the invention are evident from the following description, the following claims and/or the accompanying figures.

The method according to the invention is used for controlling a unit of a particle beam device for imaging, analyzing and/or processing an object and/or for operating the unit of the particle beam device. The aforementioned particle beam device may be an electron beam device and/or an ion beam device. The particle beam device may comprise a particle beam generator generating charged particles. The charged particles may be electrons and/or ions.

The method according to the invention comprises the step of identifying at least one part of at least one hand of the user or at least one complete hand of a user by means of an identification unit, wherein the identification unit is at least one of: (i) a first camera unit, (ii) a first touchless motion sensor or (iii) a first wireless motion sensor. In other words, the identification unit may be the first camera unit and/or the first touchless motion sensor and/or the first wireless motion sensor. The first touchless motion sensor may be an infrared touchless motion sensor and/or a touchless motion sensor using ultrasound, high-frequency and/or microwaves. Moreover, the first touchless motion sensor may comprise a Doppler radar unit. The first wireless motion sensor may be a data glove and/or an accelerometer and/or a gravity sensor attached to the hand or to at least the part of the hand. The at least one part of the at least one hand of the user as aforementioned and mentioned above may be a single finger or at least two fingers of the user's hand.

Furthermore, the method according to the invention comprises the step of tracking an absolute movement and/or a relative movement of the at least one part of the at least one hand of the user or of the at least one complete hand of the user by means of a tracking unit, wherein the tracking unit is at least one of: (i) a second camera unit, (ii) a second touchless motion sensor or (iii) a second wireless motion sensor. In other words, the tracking unit may be the second camera unit and/or the second touchless motion sensor and/or the second wireless motion sensor. The absolute movement is an actual movement of the at least one part of the at least one hand of the user or of the at least one complete hand of the user. The relative movement of the at least one part of the at least one hand of the user or of the at least one complete hand of the user is a movement of the at least one part of the at least one hand of the user or of the at least one complete hand of the user with respect to a given part of the particle beam device, for example the tracking unit, and/or a movement of the part of the particle beam device, for example the tracking unit, with respect to the at least one part of the at least one hand of the user or the at least one complete hand of the user. The second touchless motion sensor may be an infrared touchless motion sensor and/or a touchless motion sensor using ultrasound, high-frequency and/or microwaves. Moreover, the second touchless motion sensor may comprise a Doppler radar unit. In an embodiment of the method according to invention, the first camera unit is identical to the second camera unit. Moreover, the first touchless motion sensor may be identical to the second touchless motion sensor. The second wireless motion sensor may be the data glove and/or an accelerometer and/or a gravity sensor attached to the hand or to at least a part of the hand. Moreover, the first wireless motion sensor may be identical to the second wireless motion sensor.

The identification unit may be identical to the tracking unit.

The method according to the invention further comprises the step of transforming the movement of the at least one part of the at least one hand of the user or the at least one complete hand of the user into a command for a control of the unit of the particle beam device by means of a transformation unit. For example, the transformation unit may be a processor. For example, if the unit of the particle beam device is to be moved, the movement of the at least one part of the at least one hand of the user or the at least one complete hand of the user is transformed into a movement, in particular a calculated movement, of the unit of the particle beam device. A coordinate transformation from a first coordinate system in the form of the coordinate system of the at least one part of the at least one hand of the user or the at least one complete hand of the user into a second coordinate system in the form of a coordinate system of the unit of the particle beam device is used.

Moreover, the method according to the invention comprises the step of providing the control of the unit of the particle beam device by means of the command, wherein the command is used as an input into a control unit for controlling the unit of the particle beam device. For example, the control unit is a drive unit, wherein the movement of the unit of the particle beam device is provided according to the calculated movement.

The invention provides for an accurate control of the unit of the particle beam device, for example by moving the at least one part of the at least one hand of the user or the at least one complete hand of the user, by tracking this movement of the at least one part of the at least one hand of the user or the at least one complete hand of the user and by transforming this movement of the at least one part of the at least one hand of the user or the at least one complete hand of the user into a command for controlling the unit, for example into a movement of the unit of the particle beam device. The control, in particular the movement, of the unit is proportional to the movement of the at least one part of the at least hand of the user or the at least one complete hand of the user. For example, the risk of confusing the axes of direction or axes of rotation of the movement of the unit is reduced. Moreover, the invention provides for good control of the velocity and/or the acceleration of the movement of the unit. This reduces the risk of collision of the unit of the particle beam device with further units of the particle beam device. The user is in a position to control several axes of direction and axes of rotation of the unit at once and to provide for compensation of the movement of the unit, which might be necessary as explained above.

It is additionally or alternatively provided in an embodiment of the method according to the invention that the step of tracking the absolute movement and/or relative movement of the at least one part of the at least one hand of the user or the at least one complete hand of the user comprises the step of identifying at least one direction and/or a velocity of the absolute movement and/or the relative movement of the at least one part of the at least one hand of the user or the at least one complete hand of the user. In particular, the step of tracking the absolute movement and/or the relative movement of the at least one part of the at least one hand of the user or the at least one complete hand of the user comprises identifying an orientation of the at least one part of the at least one hand of the user or the at least one complete hand of the user in a three-dimensional space. Accordingly, when the unit of the particle beam device is to be moved, the unit of the particle beam device may be proportionally moved in a first direction corresponding to a second direction of the movement of the at least one part of the at least one hand of the user or the at least one complete hand of the user with a first velocity proportionally corresponding to a second velocity of the at least one part of the at least one hand of the user or the at least one complete hand of the user.

It is additionally or alternatively provided in an embodiment of the method according to the invention that the method further comprises the step of identifying a start signal and starting the tracking of the absolute movement and/or the relative movement of the at least one part of the at least one hand of the user or the at least one complete hand of the user after having identified the start signal. In particular, the start signal may be also provided by the at least one part of the at least one hand of the user or the at least one complete hand of the user. Additionally or alternatively, the start signal may be provided by at least a part of a first hand of the user, and the absolute movement and/or the relative movement of at least a part of the second hand of the user is tracked. For example, the start signal may be identified using the identification unit and/or the tracking unit. In particular, the start signal may be a start gesture, for example a forefinger of the user pointing in a first specific direction. It is explicitly mentioned that the invention is not restricted to the aforementioned start gesture. Rather, any start gesture which is suitable for the invention may be used.

Furthermore, it is additionally or alternatively provided in an embodiment of the method according to the invention that the method further comprises a step of the at least one part of the at least one hand of the user or the at least one complete hand of the user providing a stop signal. Additionally or alternatively, the stop signal is provided by at least one part of the further hand or the complete further hand of the user. The stop signal is identified using, for example, the identification unit and/or the tracking unit. After having identified the stop signal, the control of the unit of the particle beam device is stopped, wherein the control has been triggered by the above mentioned command. If the unit of the particle beam device is to be moved, the movement of the unit of the particle beam device according to the calculated movement is stopped. The stop signal may be a stop gesture, for example the user's forefinger pointing in a second specific direction. It is explicitly mentioned that the invention is not restricted to the aforementioned stop gesture. Rather, any stop gesture which is suitable for the invention may be used.

Moreover, it is additionally or alternatively provided in an embodiment of the method according to the invention that the start signal is provided by pressing and/or touching a start button arranged at a device control unit of the particle beam device. Moreover, the stop signal may be provided by pressing and/or touching a stop button arranged at the device control unit of the particle beam device and/or by releasing the start button. One of the hands of the user may be used for pressing the start button and/or the stop button. After the stop signal has been provided, the control of the unit of the particle beam device is stopped, wherein the control has been triggered by the above mentioned command. If the unit of the particle beam device has been moved, the movement of the unit of the particle beam device according to the movement, in particular the calculated movement is stopped.

As already mentioned above, it is additionally or alternatively provided in an embodiment of the method according to the invention that the first camera unit and the second camera unit are identical. Moreover, the first touchless motion sensor and the second touchless motion sensor may be identical. Furthermore, the first wireless motion sensor and the second wireless motion sensor may be identical.

It is additionally or alternatively provided in an embodiment of the method according to the invention that the method uses an ion beam device as the particle beam device. Additionally or alternatively, the method according to the invention uses an electron beam device as the particle beam device.

As mentioned above, it is additionally or alternatively provided in an embodiment of the method according to the invention that the command is for moving the unit of the particle beam device according in particular to a movement calculated by means of the transformation unit, for example in the form of a calculation unit. When the control of the unit of the particle beam device is provided by means of the command, the movement of the unit of the particle beam device is provided by means of the control unit in the form of a drive unit. The movement of the unit of the particle beam device is provided according to the in particular calculated movement.

Moreover, it is additionally or alternatively provided in an embodiment of the method according to the invention that a manipulator for an object is used as the unit of the particle beam device. In particular, the manipulator may be a micromanipulator. The micromanipulator may be used for manipulating and/or handling an object having a small dimension, for example of a few μm or less. The micromanipulator may have a first gripper unit and a second gripper unit. The object may be hold in an area between the first gripper unit and the second gripper unit. Additionally or alternatively, the micromanipulator may comprise at least one optical fiber for providing light to the object, for example laser light for preparing the object. Furthermore, the manipulator may be moved in a three-dimensional space. For example, the manipulator may be moved in an x-direction, in a y-direction and in a z-direction being, in particular, perpendicularly arranged to each other. Additionally, the manipulator may be rotated about a first manipulator axis of rotation, about a second manipulator axis of rotation arranged, for example, perpendicular to the first manipulator axis of rotation and about a third manipulator axis of rotation arranged, for example, perpendicular to the first manipulator axis of rotation and the second manipulator axis of rotation. The manipulator may be used for lifting a cut out part of bulk material out of the bulk material and for arranging the cut out part of the bulk material at a sample holder, for example a TEM sample holder.

It is additionally or alternatively provided in an embodiment of the method according to the invention that a detector is used as the unit of the particle beam device. The detector may be a particle detector and/or a radiation detector. For example, the detector may be moved to or away from a specific detection position in an object chamber of the particle beam device. For example, the detector may be moved in an x-direction, in a y-direction and in a z-direction being, for example, perpendicularly arranged to each other. Additionally, the detector may be rotated about a first detector axis of rotation and about a second detector axis of rotation arranged, for example, perpendicular to the first detector axis of rotation. In a further embodiment, the detector may be also rotated about a third detector axis of rotation arranged, for example, perpendicular to at least one of: the first detector axis of rotation and the second detector axis of rotation. For example, the detector may comprise an electrical testing probe, a mechanical testing probe or an optical testing probe.

Furthermore, it is additionally or alternatively provided in an embodiment of the method according to the invention that a gas injection device is used as the unit of the particle beam device. In particular, the gas injection device is a gas needle of a gas injection system providing gas to an object being arranged in the object chamber of the particle beam device. For example, the gas injection device may be moved to or away from a specific injection position with respect to the object in an object chamber of the particle beam device. For example, the gas injection device may be moved in an x-direction, in a y-direction and in a z-direction being perpendicularly arranged to each other. Additionally, the gas injection device may be rotated about a first gas injection device axis of rotation and about a second gas injection device axis of rotation arranged, for example, perpendicular to the first gas injection device axis of rotation. In a further embodiment, the gas injection device may be rotated about a third gas injection device axis of rotation arranged, for example, perpendicular to at least one of: the first gas injection device axis of rotation and the second gas injection device axis of rotation.

Moreover, it is additionally or alternatively provided in an embodiment of the method according to the invention that a movable object stage for arranging an object in the object chamber of the particle beam device is used as the unit of the particle beam device. For example, the object stage may be moved in an x-direction, in a y-direction and in a z-direction being, for example, perpendicularly arranged to each other. Additionally, the object stage may be rotated about a first stage axis of rotation and about a second stage axis of rotation arranged, for example, perpendicular to the first stage axis of rotation.

It is additionally or alternatively provided in an embodiment of the method according to the invention that a movable aperture unit of the particle beam device is used as the unit of the particle beam device. For example, the aperture unit may be moved in an x-direction, in a y-direction and in a z-direction being, for example, perpendicularly arranged to each other. Additionally, the movable aperture unit may be rotated about a first movable aperture unit axis of rotation and about a second movable aperture unit axis of rotation arranged, for example, perpendicular to the first movable aperture unit axis of rotation. In a further embodiment, the movable aperture unit may be also rotated about a third movable aperture unit axis of rotation arranged, for example, perpendicular to at least one of: the first movable aperture unit axis of rotation and the second movable aperture unit axis of rotation.

It is additionally or alternatively provided in an embodiment of the method according to the invention that a high voltage control unit is used as the unit of the particle beam device, for example for adjusting an acceleration voltage of particles generated in the particle beam device. In particular, the particles generated in the particle beam device are electrons or ions.

It is additionally or alternatively provided in an embodiment of the method according to the invention that a current control unit for adjusting a current of a lens, in particular an objective lens, of the particle beam device is used as the unit of the particle beam device. Therefore, the method according to the invention is used for controlling the current control unit and, therefore, the current of the lens, in particular the objective lens.

It is additionally or alternatively provided in an embodiment of the method according to the invention that at least one electrostatic and/or magnetic device for guiding particles of the particle beam device is used as the unit of the particle beam device. The particles may be primary particles such as an electrons or ions. Moreover, the particles may be interaction particles, such as secondary particles and backscattered particles. In particular, the electrostatic and/or magnetic device may be a condenser lens, a beam blank unit, a beam shift unit and/or a unit for guiding the primary particles (that is the primary particle beam) through an opening of an aperture unit.

It is additionally or alternatively provided in an embodiment of the method according to the invention that a magnification unit for adjusting the magnification of the particle beam device is used as the unit of the particle beam device.

Moreover, it is additionally or alternatively provided in an embodiment of the method according to the invention that a scan control unit is used as the unit of the particle beam device. In particular, the scan control unit is used for starting and/or for stopping a scan over the object using the primary particles (that is the primary particle beam) of the particle beam device. Moreover, the scan control unit may be used for controlling a scan direction, a scan velocity of the primary particles (that is the primary particle beam) of the particle beam device, a scan area which the primary particle beam is guided to and/or a position of the primary particle beam on the object.

It is additionally or alternatively provided in an embodiment of the method according to the invention that a stigmator for reducing astigmatism in the particle beam device is used as the unit of the particle beam device.

It is additionally or alternatively provided in an embodiment of the method according to the invention that a switching device for choosing detection of particles and/or radiation by means of a first detector and/or by means of a second detector of the particle beam device is used as the unit of the particle beam device. In other words, the switching device is used for choosing the first detector and/or the second detector for detecting, for example, interaction particles and/or interaction radiation.

It is additionally or alternatively provided in an embodiment of the method according to the invention that a beam control unit for selecting a first particle beam comprising first charged particles or a second particle beam comprising second charged particles of the particle beam device is used as the unit of the particle beam device.

It is additionally or alternatively provided in an embodiment of the method according to the invention that a vacuum control unit for controlling a vacuum system and/or at least one valve is used as the unit of the particle beam device.

It is additionally or alternatively provided in an embodiment of the method according to the invention that at least 2 or 3 of the following units are used as the unit of the particle beam device at the same time: the manipulator, the detector, the object stage, the aperture unit, the high voltage unit, the current control unit, the electrostatic and/or magnetic device, the scan control unit, the stigmator, the switching device, the beam control unit and the vacuum control unit. In other words, at least 2 or 3 of the aforementioned units may be controlled by the movement of the at least one part of the at least one hand of the user or the at least one complete hand of the user at the same time.

The invention also relates to a further method. The further method according to the invention is also used for controlling a unit of a particle beam device for imaging, analyzing and/or processing an object and/or for operating the unit of the particle beam device. The aforementioned particle beam device may be an electron beam device and/or an ion beam device. The particle beam device may comprise a particle beam generator generating charged particles. The charged particles may be electrons and/or ions.

The further method according to the invention comprises the step of identifying a gesture provided by at least one part of at least one hand of the user or at least one complete hand of a user by means of an identification unit, wherein the identification unit is at least one of: (i) a camera unit, (ii) a touchless sensor or (iii) a wireless sensor. In other words, the identification unit may be the camera unit and/or the touchless sensor and/or the wireless sensor. The touchless sensor may be an infrared touchless sensor and/or a touchless sensor using ultrasound, high-frequency and/or microwaves. Moreover, the touchless sensor may comprise a Doppler radar unit. The wireless sensor may be a data glove and/or an accelerometer and/or a gravity sensor attached to the hand or to at least the part of the hand. The at least one part of the at least one hand of the user as aforementioned and mentioned above may be a single finger or at least two fingers of the user's hand.

Furthermore, the further method according to the invention comprises the step of selecting a command for a control of the unit of the particle beam device by means of the identified gesture. For example, the gesture is stored in a database and is associated to a specific command. This specific command is selected and, for example, loaded from the database into a control unit.

Moreover, the further method according to the invention comprises the step of providing the control of the unit of the particle beam device by means of the command, wherein the command is used as an input into the control unit for controlling the unit of the particle beam device. For example, the control unit is a drive unit, wherein the movement of the unit of the particle beam device is provided according in particular to the calculated movement.

The further method according to the invention also provides for an accurate control of the unit of the particle beam device. The control, in particular the movement, of the unit is based on the identified gesture provided by the at least one part of the at least one hand of the user or the at least one complete hand of the user. For example, the risk of confusing the axes of direction or axes of rotation of the movement of the unit is reduced. Moreover, the invention provides for good control of the velocity and/or the acceleration of the movement of the unit. This reduces the risk of collision of the unit of the particle beam device with further units of the particle beam device. The user is in a position to control several axes of direction and axes of rotation of the unit at once and to provide for compensation of the movement of the unit, which might be necessary as explained above.

It is additionally or alternatively provided in an embodiment of the further method according to the invention that the gesture is a static gesture.

It is additionally or alternatively provided in a further embodiment of the further method according to the invention that the further method comprises the following steps:
tracking of an absolute movement and/or a relative movement of the at least one part of the at least one hand of the user or the at least one complete hand of the user, and
identifying at least one of the the following (i) at least one direction of the absolute movement and/or the relative movement of the at least one part of the at least one hand of the user or the at least one complete hand of the user, and (ii) a velocity of the absolute movement and/or the relative movement of the at least one part of the at least one hand of the user or the at least one complete hand of the user.

For example, the method according to the invention may further comprise the step of transforming the movement of the at least one part of the at least one hand of the user or the at least one complete hand of the user into the command for the control of the unit of the particle beam device by means of a transformation unit. For example, the transformation unit may be a processor. For example, if the unit of the particle beam device is to be moved, the movement of the part of the hand or the complete hand of the user is transformed, for example, into a calculated movement of the unit of the particle beam device. A coordinate transformation from a first coordinate system in the form of the coordinate system of the at least one part of the at least one hand of the user or the at least one complete hand of the user into a second coordinate system in the form of a coordinate system of the unit of the particle beam device is used.

It is additionally or alternatively provided in a further embodiment of the further method according to the invention that identifying the gesture comprises identifying an orientation of the at least one part of the at least one hand of the user or the at least one complete hand of the user in a three-dimensional space.

As mentioned above, it is additionally or alternatively provided in a further embodiment of the further method according to the invention that the command is for moving the unit of the particle beam device according to a movement provided by means of the transformation unit. When providing the control of the unit of the particle beam device by means of the command, the movement of the unit of the particle beam device is provided by means of the control unit in the form of a drive unit, wherein the movement of the unit of the particle beam device is provided according to the movement provided by the transformation unit.

It is additionally or alternatively provided in an embodiment of the further method according to the invention that the further method further comprises the step of identifying a start signal and starting the identifying of the gesture provided by the at least one part of the at least one hand of the user or the at least one complete hand of the user. In particular, the start signal may be also provided by the at least one part of the at least one hand of the user or the at least one complete hand of the user. For example, the start signal may be identified using the identification unit. In particular, the start signal may be a start gesture, for example a forefinger of the user pointing in a first specific direction. It is explicitly mentioned that the invention is not restricted to the aforementioned start gesture. Rather, any start gesture which is suitable for the invention may be used.

Furthermore, it is additionally or alternatively provided in an embodiment of the further method according to the invention that the further method further comprises a step of the at least one part of the at least one hand of the user or the at least one complete hand of the user providing a stop signal. Additionally or alternatively, the stop signal is provided by at least one part of the further hand or the complete further hand of the user. The stop signal is identified using, for example, the identification unit. After having identified the stop signal, the control of the unit of the particle beam device is stopped, wherein the control has been triggered by the above mentioned command. If the unit of the particle beam device is to be moved, the movement of the unit of the particle beam device according in particular to the calculated movement is stopped. The stop signal may be a stop gesture, for example the user's forefinger pointing in a second specific direction. It is explicitly mentioned that the invention is not restricted to the aforementioned stop gesture. Rather, any stop gesture which is suitable for the invention may be used.

Moreover, it is additionally or alternatively provided in an embodiment of the further method according to the invention that the start signal is provided by pressing and/or touching a start button arranged at a device control unit of the particle beam device. Moreover, the stop signal may be provided by pressing and/or touching a stop button arranged at the device control unit of the particle beam device and/or by releasing the start button. One of the hands of the user may be used for pressing the start button and/or the stop button. After the stop signal has been provided, the control of the unit of the particle beam device is stopped, wherein the control has been triggered by the above mentioned command. If the unit of the particle beam device has been moved, the movement of the unit of the particle beam device according in particular to the calculated movement is stopped.

It is additionally or alternatively provided in an embodiment of the further method according to the invention that the further method uses an ion beam device as the particle beam device. Additionally or alternatively, the further method according to the invention uses an electron beam device as the particle beam device.

It is additionally or alternatively provided in an embodiment of the further method according to the invention that the further method uses at least one of the above mentioned or below mentioned units of the particle beam device. Therefore, the explanations given above and below with respect to such units also apply to the further method of the invention.

The invention also refers to a computer program product comprising a program code which may be loaded or is loaded into a processor and which, when being executed, controls a particle beam device in such a way that a method comprising at least one of the above mentioned or further below mentioned steps or a combination of at least two of the above mentioned or further below mentioned steps is carried out.

The invention also refers to a particle beam device for imaging, analyzing and/or processing an object. The particle beam device according to the invention comprises at least one particle beam generator for generating a primary particle beam comprising charged particles. The charged particles may be, for example, electrons or ions. Moreover, the particle beam device according to the invention also has at least one objective lens for focusing the primary particle beam onto the object. Furthermore, the particle beam device according to the invention has at least one detector for detecting interaction particles and/or interaction radiation, the interaction particles and interaction radiation being generated when the primary particle beam impinges on the object. The interaction particles may be secondary particles and/or backscattered particles, in particular secondary electrons and backscattered electrons. The interaction radiation may be X-rays and/or cathodoluminescence light.

Moreover, the particle beam device according to the invention comprises at least one identification unit, wherein the identification unit is at least one of: (i) a camera unit, (ii) a touchless sensor or (iii) a wireless sensor. In other words, the identification unit may be the camera unit and/or the touchless sensor and/or the wireless sensor. The touchless sensor may be an infrared touchless sensor and/or a touchless sensor using ultrasound, high-frequency and/or microwaves. Moreover, the touchless sensor may comprise a Doppler radar unit. The wireless sensor may be a data glove and/or an accelerometer and/or a gravity sensor attached to the hand or to at least part of the hand.

Moreover, the particle beam device according to the invention comprises at least one unit to be controlled. Furthermore, the particle beam device according to the invention comprises a transformation unit for providing a command for controlling the unit based on the identified at least one part of at least one hand of a user or at least one complete hand of the user. The transformation unit may be a processor. Additionally, the particle beam device according to the invention comprises a control unit for providing control of the unit according to the command, for example a calculated movement. The control unit may be a drive unit, for example a motor, in particular a stepper motor or a piezo motor. It is explicitly mentioned that the control unit is not restricted to the aforementioned embodiments. Rather, the control unit may be any control unit which is suitable for the invention.

An embodiment of the particle beam device according to the invention additionally or alternatively comprises at least one processor into which a computer program product as mentioned above is loaded.

An embodiment of the particle beam device according to the invention additionally or alternatively comprises that the transformation unit is designed for transforming a movement of the at least one part of the at least one hand of the user or the at least one complete hand of the user into the command for controlling the unit.

An embodiment of the particle beam device according to the invention additionally or alternatively comprises the following features:
the camera unit is a first camera unit, the touchless sensor is a first touchless motion sensor and the wireless sensor is a first wireless motion sensor; and wherein
the particle beam device further comprises at least one tracking unit for tracking a movement of the at least one part of the at least one hand of the user or the at least one complete hand of the user, wherein the tracking unit is at least one of: (i) a second camera unit, (ii) a second touchless motion sensor or (iii) a second wireless motion sensor.

In other words, the tracking unit may be the second camera unit and/or the second touchless motion sensor and/or the second wireless motion sensor. The second touchless motion sensor may be an infrared touchless motion sensor and/or a touchless motion sensor using ultrasound, high-frequency and/or microwaves. Moreover, the second touchless motion sensor may comprise a Doppler radar unit. The second wireless motion sensor may be a data glove and/or an accelerometer and/or a gravity sensor attached to the hand or to at least part of the hand.

An embodiment of the particle beam device according to the invention additionally or alternatively comprises the following features:
the first camera unit is identical to the second camera unit;
the first touchless motion sensor is identical to the second touchless motion sensor;
the first wireless motion sensor is identical to the second wireless motion sensor.

The unit to be controlled may be any unit of the particle beam device, for example any movable unit of the particle beam device. Some embodiments of the unit are given below.

An embodiment of the particle beam device according to the invention additionally or alternatively comprises a manipulator for an object as the unit of the particle beam device. In particular, the manipulator may be a micromanipulator. The micromanipulator may have a first gripper unit and a second gripper unit. The object may be hold in an area between the first gripper unit and the second gripper unit. Additionally or alternatively, the micromanipulator may comprise at least one optical fiber for providing light to the object, for example laser light for preparing the object. In particular, the manipulator may be moved in a three-dimensional space. For example, the manipulator may be moved in an x-direction, in a y-direction and in a z-direction being perpendicular to each other. Additionally, the manipulator may be rotated about a first manipulator axis of rotation, about a second manipulator axis of rotation arranged, for example, perpendicular to the first manipulator axis of rotation, and about a third manipulator axis of rotation arranged, for example, perpendicular to the first manipulator axis of rotation and the second manipulator axis of rotation. The manipulator may be used for lifting a cut out part of bulk material out of the bulk material and for arranging the cut out part of the bulk material at a sample holder. For example, the manipulator may comprise an electrical testing probe, a mechanical testing probe or an optical testing probe.

Another embodiment of the particle beam device according to the invention additionally or alternatively comprises a detector as the unit of the particle beam device. The detector may be a particle detector and/or a radiation detector. For example, the detector may be moved to or away from a specific detection position in an object chamber of the particle beam device. For example, the detector may be moved in an x-direction, in a y-direction and in a z-direction being, for example, perpendicular to each other. Additionally, the detector may be rotated about a first detector axis of rotation and about a second detector axis of rotation arranged, for example, perpendicular to the first detector axis of rotation. In a further embodiment, the detector may be also rotated about a third detector axis of rotation arranged, for example, perpendicular to at least one of: the first detector axis of rotation and the second detector axis of rotation. For example, the detector may comprise an electrical testing probe, a mechanical testing probe or an optical testing probe.

An embodiment of the particle beam device according to the invention additionally or alternatively comprises a gas injection device as the unit of the particle beam device. In particular, the gas injection device is a gas needle of a gas injection system providing gas to an object being arranged in the object chamber of the particle beam device. For example, the gas injection device may be moved to or away from a specific injection position with respect to the object in the object chamber of the particle beam device. For example, the gas injection device may be moved in an x-direction, in a y-direction and in a z-direction being, for example, perpendicular to each other. Additionally, the gas injection device may be rotated about a first gas injection device axis of rotation and about a second gas injection device axis of rotation arranged, for example, perpendicular to the first gas injection device axis of rotation. In a further embodiment, the gas injection device may be also rotated about a third gas injection device axis of rotation arranged, for example, perpendicular to at least one of: the first gas injection device axis of rotation and the second gas injection device axis of rotation.

A further embodiment of the particle beam device according to the invention additionally or alternatively comprises a movable object stage for arranging an object in the object chamber of the particle beam device as the unit of the particle beam device. For example, the object stage may be moved in an x-direction, in a y-direction and in a z-direction being, for example, perpendicular to each other. Additionally, the object stage may be rotated about a first stage axis of rotation and about a second stage axis of rotation arranged, for example, perpendicular to the first stage axis of rotation. In a further embodiment, the object stage may also be rotated about a third stage axis of rotation arranged, for example, perpendicular to at least one of: the first stage axis of rotation and the second stage axis of rotation.

An embodiment of the particle beam device according to the invention additionally or alternatively comprises a movable aperture unit as the unit of the particle beam device. For example, the aperture unit may be moved in an x-direction, in a y-direction and in a z-direction being, for example, perpendicular to each other. Additionally, the movable aperture unit may be rotated about a first movable aperture unit axis of rotation and about a second movable aperture unit axis of rotation arranged, for example, perpendicular to the first movable aperture unit axis of rotation. In a further embodiment, the movable aperture unit may also be rotated about a third movable aperture unit axis of rotation arranged, for example, perpendicular to at least one of: the first movable aperture unit axis of rotation and the second movable aperture unit axis of rotation.

It is additionally or alternatively provided in an embodiment of the particle beam device according to the invention that the particle beam device comprises a high voltage control unit as the unit of the particle beam device, for example for adjusting an acceleration voltage of particles generated in the particle beam device. In particular, the particles generated in the particle beam device are electrons or ions.

It is additionally or alternatively provided in an embodiment of the particle beam device according to the invention that the particle beam device comprises a current control unit for adjusting a current of a lens, in particular an objective lens, of the particle beam device as the unit of the particle beam device.

It is additionally or alternatively provided in an embodiment of the particle beam device according to the invention that the particle beam device comprises at least one electrostatic and/or magnetic device for guiding particles of the particle beam device as the unit of the particle beam device. The particles may be primary particles such as electrons or ions. Moreover, the particles may be interaction particles, such as secondary particles and backscattered particles. In particular, the electrostatic and/or magnetic device may be a condenser lens, a beam blank unit, a beam shift unit and/or a unit for guiding the primary particles (that is the primary particle beam) through an opening of an aperture unit.

It is additionally or alternatively provided in an embodiment of the particle beam device according to the invention that the particle beam device comprises a magnification unit for adjusting the magnification of the particle beam device as the unit of the particle beam device.

It is additionally or alternatively provided in an embodiment of the particle beam device according to the invention that the particle beam device comprises a scan control unit as the unit of the particle beam device. In particular, the scan control unit is used for starting and/or for stopping a scan over the object using the primary particles (that is the primary particle beam) of the particle beam device. Moreover, the scan control unit may be used for controlling a scan direction, a scan velocity of the primary particles (that is the primary particle beam) of the particle beam device, a scan area which the primary particle beam is guided to and/or a position of the primary particle beam on the object.

It is additionally or alternatively provided in an embodiment of the particle beam device according to the invention that the particle beam device comprises a stigmator for reducing astigmatism in the particle beam device as the unit of the particle beam device.

It is additionally or alternatively provided in an embodiment of the particle beam device according to the invention that the particle beam device comprises a switching device for choosing detection of particles and/or radiation by means of a first detector and/or by means of a second detector of the particle beam device as the unit of the particle beam device. In other words, the switching device is used for choosing the first detector and/or the second detector for detecting, for example, interaction particles and/or interaction radiation.

It is additionally or alternatively provided in an embodiment of the particle beam device according to the invention that the particle beam device comprises a beam control unit for selecting a first particle beam comprising first charged particles or a second particle beam comprising second charged particles of the particle beam device as the unit of the particle beam device.

It is additionally or alternatively provided in an embodiment of the particle beam device according to the invention that the particle beam device comprises a vacuum control unit for controlling a vacuum system and/or at least one valve as the unit of the particle beam device.

It is additionally or alternatively provided in an embodiment of the particle beam device according to the invention that the particle beam generator is a first particle beam generator and that the primary particle beam is a first primary particle beam comprising first charged particles. The objective lens is a first objective lens for focusing the first primary particle beam onto the object. The particle beam device according to the embodiment of the invention further comprises a second particle beam generator for generating a second primary particle beam comprising second charged particles and a second objective lens for focusing the second primary particle beam onto the object. The second charged particles may be electrons and/or ions.

It is additionally or alternatively provided in a further embodiment of the particle beam device that the particle beam device is at least one of the following: an electron beam device and an ion beam device. In particular, the particle beam device may be both an electron beam device and an ion beam device. The electron beam device and the ion beam device may be arranged at an angle to each other, for example at an angle in the range of 45° to 90°, wherein the boundaries are included in this range. In particular, the electron beam device and the ion beam device may be arranged at an angle of 54° to each other. However, the invention is not restricted to the above-mentioned angles. Rather, any angle between the electron beam device and the ion beam device which is suitable for the invention may be used.

Embodiments of the invention described herein will be explained in more detail in the following text with reference to the figures, in which:

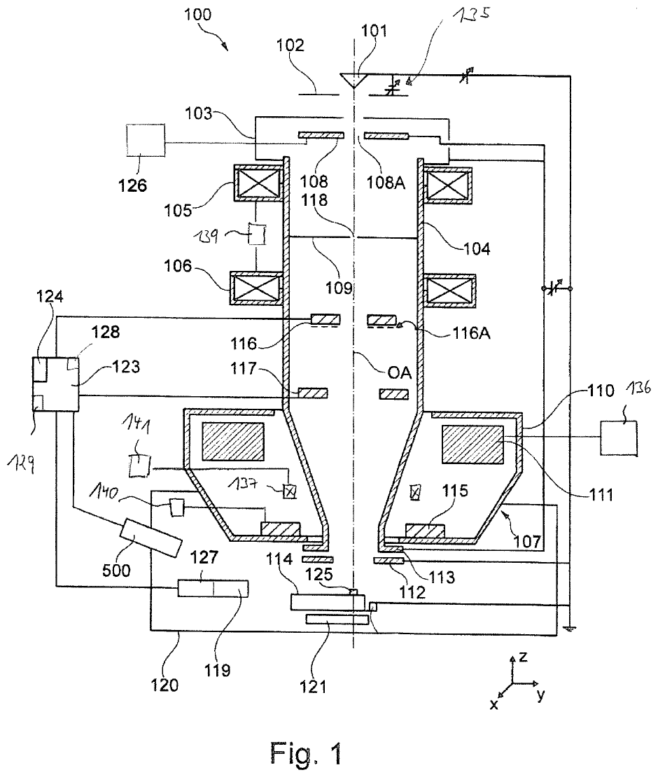

FIG. 1 shows a first exemplary embodiment of a particle beam device;

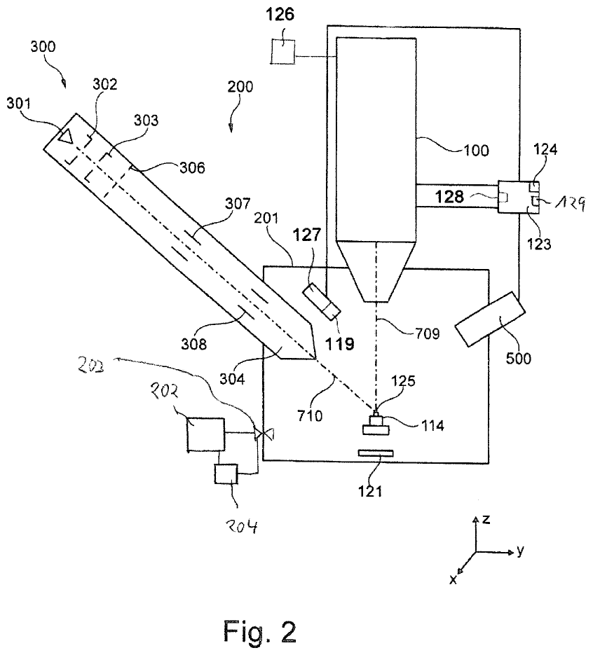

FIG. 2 shows a second exemplary embodiment of a particle beam device;

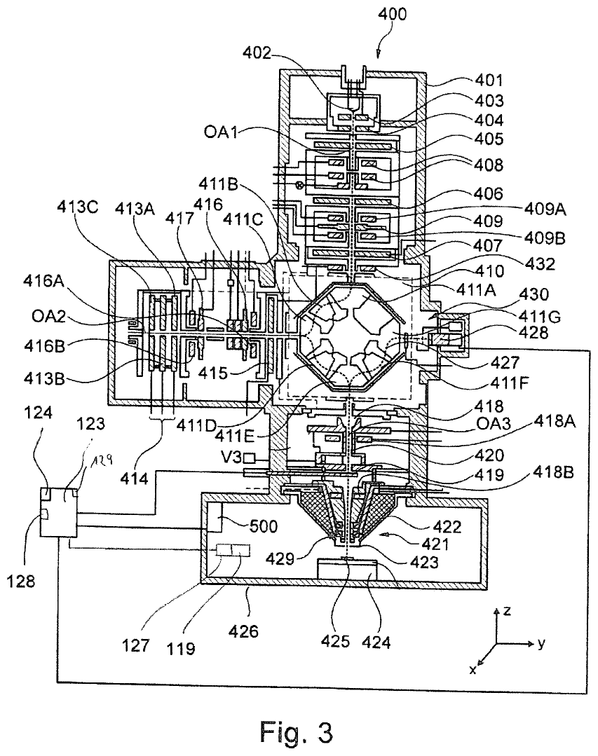

FIG. 3 shows a third exemplary embodiment of a particle beam device;

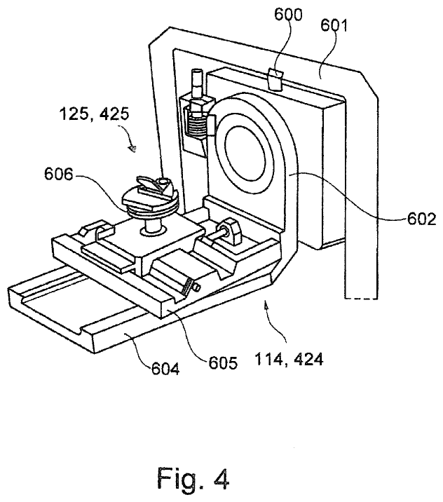

FIG. 4 shows a schematic illustration of an exemplary embodiment of a movable object stage for a particle beam device;

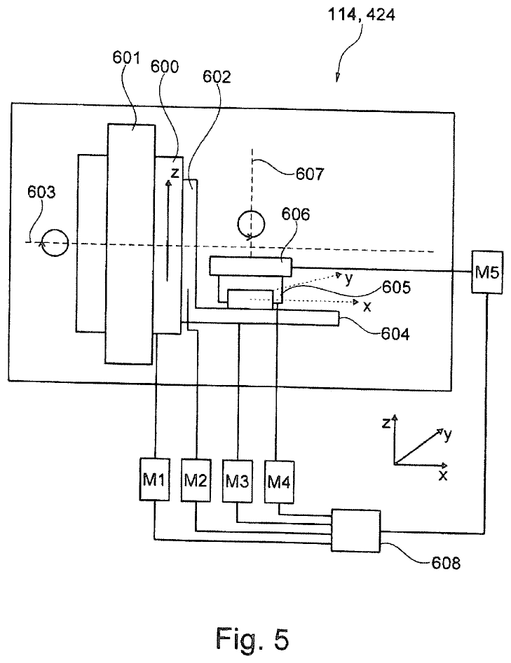

FIG. 5 shows a further schematic illustration of the object stage according to FIG. 4;

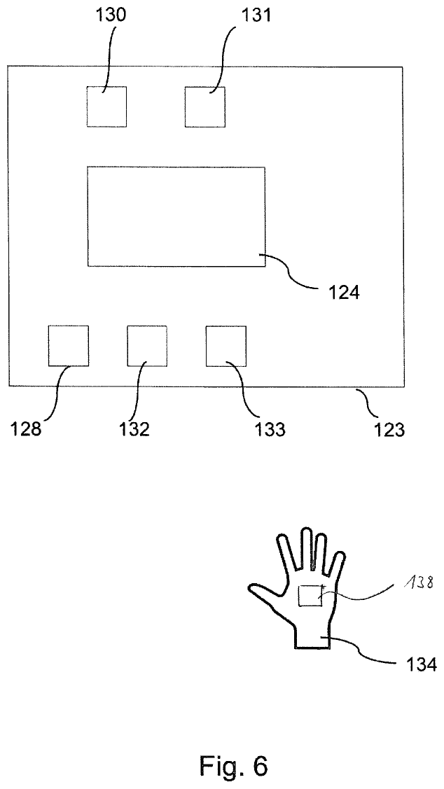

FIG. 6 shows a schematic illustration of a control unit for a particle beam device;

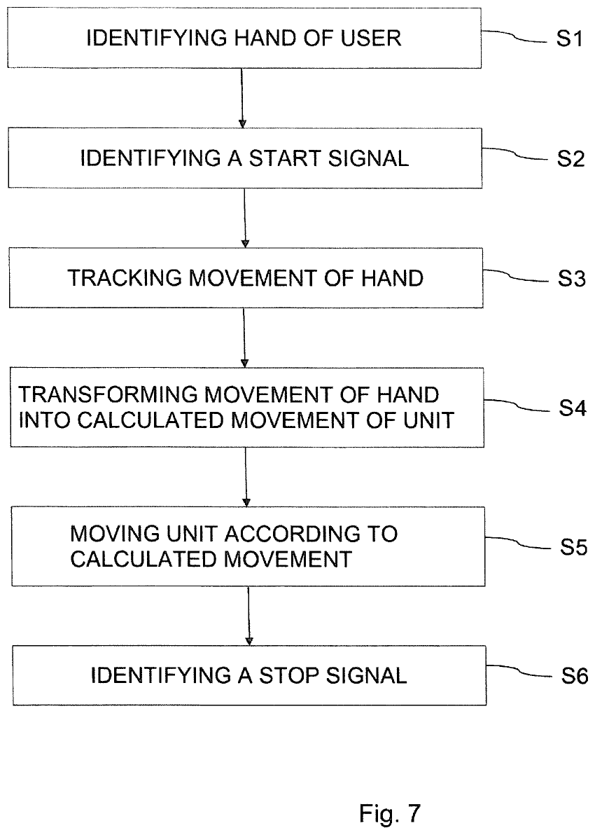

FIG. 7 shows an exemplary embodiment of a method for moving and operating a movable unit of a particle beam device; and

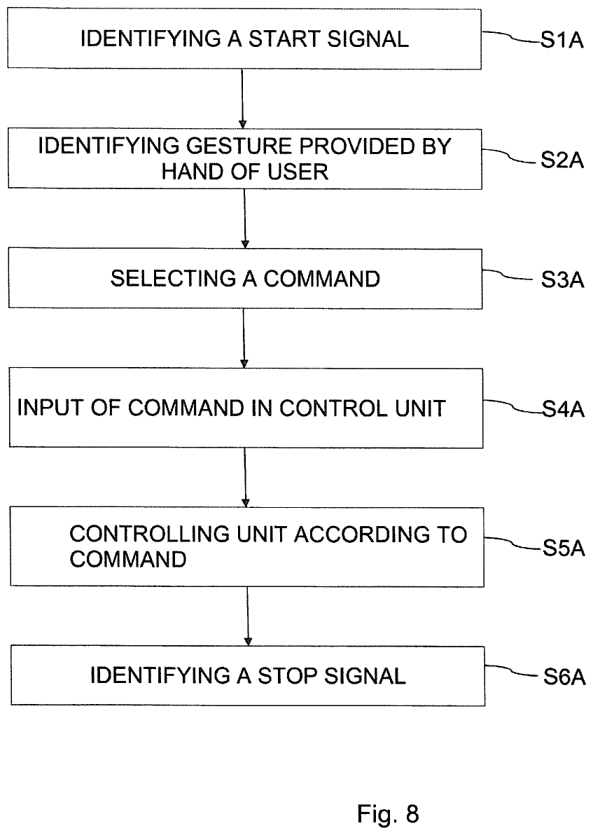

FIG. 8 shows a further exemplary embodiment of a method for controlling an unit of a particle beam device.

The invention is now explained in more detail using as example a particle beam device in the form of an SEM and in the form of a combination device, which has an electron beam column and an ion beam column. Reference is explicitly made to the fact that the invention may be used in any particle beam device, in particular in any electron beam device and/or in any ion beam device.

FIG. 1 shows a schematic illustration of an SEM 100. The SEM 100 comprises a first beam generator in the form of an electron source 101, which is embodied as a cathode. Further, the SEM 100 is provided with an extraction electrode 102 and with an anode 103, which is arranged at one end of a beam-guiding tube 104 of the SEM 100. By way of example, the electron source 101 is embodied as a thermal field emitter. However, the invention is not restricted to such an electron source 101. Rather, any electron source is utilizable.

Electrons emerging from the electron source 101 form a primary electron beam. The electrons are accelerated to the anode potential due to a potential difference between the electron source 101 and the anode 103. In the exemplary embodiment depicted here, the anode potential is 1 kV to 20 kV, e.g. 5 kV to 15 kV, in particular 8 kV, in relation to a ground potential of a housing of an object chamber 120. However, alternatively it could be at ground potential.

Two condenser lenses, namely a first condenser lens 105 and a second condenser lens 106, are arranged at the beam-guiding tube 104. In FIG. 1, parting from the electron source 101 as viewed in the direction of a first objective lens 107, the first condenser lens 105 is arranged first, followed by the second condenser lens 106. Reference is explicitly made to the fact that further exemplary embodiments of the SEM 100 may have only a single condenser lens. A first aperture unit 108 is arranged between the anode 103 and the first condenser lens 105. Together with the anode 103 and the beam-guiding tube 104, the first aperture unit 108 is at a high voltage potential, namely the potential of the anode 103, or it is connected to ground. The first aperture unit 108 has numerous first apertures 108A, of which one is depicted in FIG. 1. Two first apertures 108A may be present, for example. Each one of the numerous first apertures 108A has a different aperture diameter. By means of an adjustment mechanism 126, it is possible to place a desired first aperture 108A onto an optical axis OA of the SEM 100. For example, the first aperture unit 108 may be moved in an x-direction (namely a first aperture unit axis), in a y-direction (namely a second aperture unit axis) and in a z-direction (namely a third aperture unit axis), which are perpendicular to each other, using the adjustment mechanism 126. The adjustment mechanism 126 may be a drive unit, in particular a motor, for example a stepper motor or a piezo motor. It is explicitly mentioned that the drive unit is not restricted to the aforementioned embodiments. Rather, the drive unit may be any drive unit which is suitable for the invention.

Reference is explicitly made to the fact that, in further exemplary embodiments, the first aperture unit 108 may be provided with only a single aperture 108A. In these exemplary embodiments, an adjustment mechanism may be omitted. The first aperture unit 108 is then designed to be stationary.

A stationary second aperture unit 109 is arranged between the first condenser lens 105 and the second condenser lens 106. As an alternative thereto, provision may be made for the second aperture unit 109 to be movable.

The first objective lens 107 has pole pieces 110, in which a bore is formed. The beam-guiding tube 104 is guided through this bore. A coil 111 is arranged in the pole pieces 110.

An electrostatic retardation device is arranged in a lower region of the beam-guiding tube 104. It has a single electrode 112 and a tube electrode 113. The tube electrode 113 is arranged at one end of the beam-guiding tube 104, which faces an object 125 that is arranged on an object stage 114. Together with the beam-guiding tube 104, the tube electrode 113 is at the potential of the anode 103, while the single electrode 112 and the object 125 are at a lower potential in relation to the potential of the anode 103. In the present case, this is the ground potential of the housing of the object chamber 120. In this manner, the electrons of the primary electron beam may be decelerated to a desired energy which is required for examining the object 125.

The SEM 100 further comprises a scanning device 115, by means of which the primary electron beam may be deflected and scanned over the object 125. In doing so, the electrons of the primary electron beam interact with the object 125. As a result of the interaction, interaction particles are generated, which are detected. In particular, electrons are emitted from the surface of the object 125—the so-called secondary electrons—or electrons of the primary electron beam are scattered back—the so-called backscattered electrons—as interaction particles.

The object 125 and the single electrode 112 may also be at different potentials and potentials different than ground. It is thereby possible to set the location of the retardation of the primary electron beam in relation to the object 125. By way of example, if the retardation is carried out quite close to the object 125, imaging aberrations become smaller.

A detector arrangement comprising a first detector 116 and a second detector 117 is arranged in the beam-guiding tube 104 for detecting the secondary electrons and/or the backscattered electrons, wherein the first detector 116 is arranged on the source-side along the optical axis OA, while the second detector 117 is arranged on the object-side along the optical axis OA in the beam-guiding tube 104. The first detector 116 and the second detector 117 are arranged offset from one another in the direction of the optical axis OA of the SEM 100. The first detector 116 and the second detector 117 each have a passage opening, through which the primary electron beam may pass. The first detector 116 and the second detector 117 are approximately at the potential of the anode 103 and of the beam-guiding tube 104. The optical axis OA of the SEM 100 extends through the respective passage openings.

The second detector 117 serves principally for detecting secondary electrons. Upon emerging from the object 125, the secondary electrons initially have a low kinetic energy and arbitrary directions of motion. By means of the strong extraction field emanating from the tube electrode 113, the secondary electrons are accelerated in the direction of the first objective lens 107. The secondary electrons enter the first objective lens 107 approximately parallel. The beam diameter of the beam of secondary electrons remains small in the first objective lens 107 as well. The first objective lens 107 then has a strong effect on the secondary electrons and generates a comparatively short focus of the secondary electrons with sufficiently steep angles with respect to the optical axis OA, such that the secondary electrons diverge far apart from one another downstream of the focus and are incident on the active area of the second detector 117. By contrast, only a small proportion of electrons that are backscattered at the object 125—that is to say backscattered electrons which have a relatively high kinetic energy in comparison with the secondary electrons emerging from the object 125—is detected by the second detector 117. The high kinetic energy and the angles of the backscattered electrons with respect to the optical axis OA upon emerging from the object 125 have the effect that a beam waist, that is to say a beam region having a minimum diameter, of the backscattered electrons lies in the vicinity of the second detector 117. A large portion of the backscattered electrons passes through the passage opening of the second detector 117. Therefore, the first detector 116 substantially serves to detect the backscattered electrons.

In a further embodiment of the SEM 100, the first detector 116 may additionally be embodied with an opposing field grating 116A. The opposing field grating 116A is arranged at the side of the first detector 116 directed toward the object 125. With respect to the potential of the beam-guiding tube 104, the opposing field grating 116A has a negative potential such that only backscattered electrons with high energy pass through the opposing field grating 116A to the first detector 116. Additionally or alternatively, the second detector 117 has a further opposing field grating, whose design and function are analogous to those of the aforementioned opposing field grating 116A of the first detector 116.

The detection signals generated by the first detector 116 and the second detector 117 are used to generate an image or images of the surface of the object 125.

Reference is explicitly made to the fact that for the sake of clarity, in the figures, the apertures of the first aperture unit 108 and of the second aperture unit 109, as well as the passage openings of the first detector 116 and of the second detector 117 appear disproportionately large. The passage openings of the first detector 116 and of the second detector 117 have an extent perpendicular to the optical axis OA in the range of 0.5 mm to 5 mm. By way of example, they are of circular design and have a diameter in the range of 1 mm to 3 mm perpendicular to the optical axis OA.

The second aperture unit 109 is configured as a pinhole aperture in the exemplary embodiment depicted here and provided with a second aperture 118 for the passage of the primary electron beam, which has an extent in the range from 5 μm to 500 μm, e.g. 35 μm. As an alternative thereto, provision is made in a further embodiment for the second aperture unit 109 to be provided with a plurality of apertures, which can be displaced mechanically with respect to the primary electron beam or which can be reached by the primary electron beam by the use of electrical and/or magnetic deflection elements. The second aperture unit 109 is embodied as a pressure stage unit. It separates a first region, in which the electron source 101 is arranged and in which an ultra-high vacuum (10⁻⁷ hPa to 10⁻¹² hPa) prevails, from a second region, which has a high vacuum (10⁻³ hPa to 10⁻⁷ hPa). The second region is the intermediate pressure region of the beam-guiding tube 104, which leads to the object chamber 120.

The object chamber 120 is under vacuum. For the purpose of generating the vacuum, a pump (not illustrated) is arranged at the object chamber 120. In the exemplary embodiment illustrated in FIG. 1, the object chamber 120 is operated in a first pressure range or in a second pressure range. The first pressure range comprises only pressures of less than or equal to 10⁻³ hPa, and the second pressure range comprises only pressures of greater than 10⁻³ hPa. To ensure said pressure ranges, the object chamber 120 is vacuum-sealed.

The object stage 114 is embodied to be movable in three directions arranged perpendicular to each other, namely in an x-direction (first stage axis), in a y-direction (second stage axis) and in a z-direction (third stage axis). Moreover, the object stage 114 can be rotated about two rotational axes which are arranged perpendicular to one another, namely a first stage rotation axis and a second stage rotation axis.

The SEM 100 further comprises a third detector 121, which is arranged in the object chamber 120. More precisely, the third detector 121 is arranged downstream of the object stage 114, as seen from the electron source 101 along the optical axis OA. The object stage 114 can be rotated in such a way that the primary electron beam can be radiated through the object 125. When the primary electron beam passes through the object 125 to be examined, the electrons of the primary electron beam interact with the material of the object 125 to be examined. The electrons passing through the object 125 to be examined are detected by the third detector 121.

Arranged at the object chamber 120 is a radiation detector 500, which is used to detect interaction radiation, for example x-ray radiation and/or cathodoluminescence. The radiation detector 500, the first detector 116 and the second detector 117 are connected to a device control unit 123 which has a monitor 124 and a database 129. The third detector 121 is also connected to the device control unit 123. For reasons of clarity, this connection is not illustrated. The device control unit 123 processes detection signals that are generated by the first detector 116, the second detector 117, the third detector 121 and/or the radiation detector 500 and displays said detection signals in the form of images on the monitor 124.

Further, the SEM 100 has a movable unit 119 which may be a manipulator, a chamber detector and/or a gas injection device.

The manipulator may be a micromanipulator. The manipulator may be used for lifting a cut out part of bulk material out of the bulk material and for arranging the cut out part of the bulk material on a sample holder. The micromanipulator may have a first gripper unit and a second gripper unit. Additionally or alternatively, the micromanipulator may comprise at least one optical fiber for providing light to the object 125, for example laser light for preparing the object 125. Moreover, the micromanipulator may comprise an electrical testing probe, a mechanical testing probe or an optical testing probe.

The chamber detector may be a particle detector and/or a radiation detector. For example, the chamber detector may be moved to or away from a specific detection position in the object chamber 120 of the SEM 100. Moreover, the chamber detector may comprise an electrical testing probe, a mechanical testing probe or an optical testing probe.

The gas injection device may be a gas needle, an assembly of several gas needles or any other gas injection unit of a gas injection system providing gas to the object 125. For example, the gas injection device may be moved to or away from a specific injection position with respect to the object 125 in the object chamber 120.

The movable unit 119 is connected to a drive unit 127 and may be moved in an x-direction (namely a first unit direction), in a y-direction (namely a second unit direction) and in a z-direction (namely a third unit direction) using the drive unit 127. All directions are perpendicular to each other. Additionally, the movable unit 119 may be rotated about a first unit axis of rotation and about a second unit axis of rotation arranged perpendicular to the first unit axis of rotation, wherein the drive unit 127 is used for the rotation. The drive unit 127 may be a motor, for example a stepper motor or a piezo motor. It is explicitly mentioned that the drive unit 127 is not restricted to the aforementioned embodiments. Rather, the drive unit 127 may be any drive unit which is suitable for the invention.

The SEM 100 further comprises a high voltage control unit 135 for adjusting the acceleration voltage of the electrons of the primary electron beam.

Moreover, the SEM 100 comprises a current control unit 136 for adjusting a current of the objective lens 107.

The SEM 100 also comprises a stigmator 137 for reducing astigmatism in the SEM 100. The stigmator 137 is connected to a stigmator control unit 141.

Furthermore, the SEM 100 comprises a condenser control unit 139 connected to the first condenser lens 105 and the second condenser lens 106.

Moreover, the SEM 100 comprises a scan control unit 140 connected to the scanning device 115.

Furthermore, the SEM 100 comprises a processor 128 into which a program code is loaded for controlling the SEM 100 in such a way that a method according to the invention is carried out.

FIG. 2 shows a particle beam device in the form of a combination device 200. The combination device 200 has two particle beam columns.

On one hand, the combination device 200 is provided with the SEM 100, as depicted in FIG. 1, but without the object chamber 120. Rather, the SEM 100 is arranged at an object chamber 201. The object chamber 201 is under vacuum. For the purpose of generating the vacuum, a vacuum system 202 comprising a pump is connected to a valve 203 arranged at the object chamber 201. The vacuum system 202 and the valve 203 are connected to a vacuum control unit 204. In the exemplary embodiment illustrated in FIG. 2, the object chamber 201 is operated in a first pressure range or in a second pressure range. The first pressure range comprises only pressures of less than or equal to 10⁻³ hPa, and the second pressure range comprises only pressures of greater than 10⁻³ hPa. To ensure said pressure ranges, the object chamber 201 is vacuum-sealed.

The third detector 121 is arranged in the object chamber 201. The SEM 100 serves to generate a first particle beam, namely the primary electron beam described further above, and has an optical axis like the one specified above, denoted by reference sign 709 in FIG. 2 and also referred to as first beam axis.

On the other hand, the combination device 200 is provided with an ion beam device 300, which is likewise arranged at the object chamber 201. The ion beam device 300 likewise has an optical axis, which is denoted by reference sign 710 in FIG. 2 and which is also referred to as second beam axis.

The SEM 100 is arranged vertically in relation to the object chamber 201. By contrast, the ion beam device 300 is arranged inclined by an angle of approximately 50° in relation to the SEM 100. It has a second beam generator in the form of an ion beam generator 301. Ions, which form a second particle beam in the form of an ion beam, are generated by the ion beam generator 301. The ions are accelerated by means of an extraction electrode 302, which is at a predeterminable potential. The second particle beam then passes through ion optics of the ion beam device 300, wherein the ion optics comprise a condenser lens 303 and a second objective lens 304. The second objective lens 304 ultimately generates an ion probe, which is focused on the object 125 arranged on an object stage 114.

An adjustable or selectable aperture unit 306, a first electrode arrangement 307 and a second electrode arrangement 308 are arranged above the second objective lens 304 (i.e. in the direction of the ion beam generator 301), wherein the first electrode arrangement 307 and the second electrode arrangement 308 are embodied as scanning electrodes. The second particle beam is scanned over the surface of the object 125 by means of the first electrode arrangement 307 and the second electrode arrangement 308, with the first electrode arrangement 307 acting in a first direction and the second electrode arrangement 308 acting in a second direction, which is counter to the first direction. This way, scanning is carried out in e.g. an x-direction. Scanning in a y-direction perpendicular thereto is effected by further electrodes (not depicted here), which are rotated by 90°, at the first electrode arrangement 307 and at the second electrode arrangement 308.

In the exemplary embodiment shown in FIG. 2, the object stage 114 is also embodied to be movable in three directions arranged perpendicular to each other, namely in an x-direction (first stage axis), in a y-direction (second stage axis) and in a z-direction (third stage axis). Moreover, the object stage 114 can be rotated about two rotational axes which are arranged perpendicular to one another, namely a first stage rotation axis and a second stage rotation axis.

The distances depicted in FIG. 2 between the individual units of the combination device 200 appear disproportionately large in order to better illustrate the individual units of the combination device 200.

Arranged at the object chamber 201 is a radiation detector 500, which is used to detect interaction radiation, for example x-ray radiation and/or cathodoluminescence. The radiation detector 500 is connected to the device control unit 123, which has a monitor 124 and a database 129. The device control unit 123 processes detection signals that are generated by the first detector 116, the second detector 117 (not illustrated in FIG. 2), the third detector 121 and/or the radiation detector 500 and displays said detection signals in the form of images on the monitor 124.

Further, the combination device 200 has a movable unit 119 which may be a manipulator, a chamber detector and/or a gas injection device.

As above mentioned, the manipulator may be a micromanipulator. The manipulator may be used for lifting a cut out part of the object 125 out of the object 125 and for arranging the cut out part of the object 125 on a TEM sample holder. The micromanipulator may have a first gripper unit and a second gripper unit. Additionally or alternatively, the micromanipulator may comprise at least one optical fiber for providing light to the object 125, for example laser light for preparing the object 125. Moreover, the manipulator may comprise an electrical testing probe, a mechanical testing probe or an optical testing probe.

The chamber detector may be a particle detector and/or a radiation detector. For example, the chamber detector may be moved to or away from a specific detection position in the object chamber 201 of the combination device 200. Moreover, the chamber detector may comprise an electrical testing probe, a mechanical testing probe or an optical testing probe.

The gas injection device may be a gas needle, an assembly of several gas needles or any other gas injection unit of a gas injection system providing gas to the object 125. For example, the gas injection device may be moved to or away from a specific injection position with respect to the object 125 in the object chamber 201 of the combination device 200.

The movable unit 119 is connected to a drive unit 127 and may be moved in an x-direction (namely a first unit direction), in a y-direction (namely a second unit direction) and in a z-direction (namely a third unit direction) using the drive unit 127. All directions are perpendicular to each other. Additionally, the movable unit 119 may be rotated about a first unit axis of rotation and about a second unit axis of rotation arranged perpendicular to the first unit axis of rotation, wherein the drive unit 127 is used for the rotation. The drive unit 127 may be a motor, for example a stepper motor or a piezo motor. It is explicitly mentioned that the drive unit 127 is not restricted to the aforementioned embodiments. Rather, the drive unit may be any drive unit which is suitable for the invention.

Furthermore, the combination device 200 comprises a processor 128 into which a program code is loaded for controlling the combination device 200 in such a way that a method according to the invention is carried out.

FIG. 3 is a schematic illustration of a further exemplary embodiment of a particle beam device according to the invention. This exemplary embodiment of the particle beam device is denoted by reference sign 400 and said exemplary embodiment comprises a mirror corrector for correcting e.g. chromatic and/or spherical aberrations. The particle beam device 400 comprises a particle beam column 401, which is embodied as an electron beam column and which substantially corresponds to an electron beam column of a corrected SEM. However, the particle beam device 400 is not restricted to an SEM with a mirror corrector. Rather, the particle beam device may comprise any type of correction units.

The particle beam column 401 comprises a particle beam generator in the form of an electron source 402 (cathode), an extraction electrode 403, and an anode 404. By way of example, the electron source 402 is embodied as a thermal field emitter. Electrons emerging from the electron source 402 are accelerated to the anode 404 due to a potential difference between the electron source 402 and the anode 404. Accordingly, a particle beam in the form of an electron beam is formed along a first optical axis OA1.

The particle beam is guided along a beam path, which corresponds to the first optical axis OA1, after the particle beam has emerged from the electron source 402. A first electrostatic lens 405, a second electrostatic lens 406, and a third electrostatic lens 407 are used to guide the particle beam.

Furthermore, the particle beam is adjusted along the beam path using a beam-guiding device. The beam-guiding device of this exemplary embodiment comprises a source adjustment unit with two magnetic deflection units 408 arranged along the first optical axis OA1. Moreover, the particle beam device 400 comprises electrostatic beam deflection units. A first electrostatic beam deflection unit 409, which is also embodied as a quadrupole in a further embodiment, is arranged between the second electrostatic lens 406 and the third electrostatic lens 407. The first electrostatic beam deflection unit 409 is likewise arranged downstream of the magnetic deflection units 408. A first multi-pole unit 409A in the form of a first magnetic deflection unit is arranged at one side of the first electrostatic beam deflection unit 409. Moreover, a second multi-pole unit 409B in the form of a second magnetic deflection unit is arranged at the other side of the first electrostatic beam deflection unit 409. The first electrostatic beam deflection unit 409, the first multi-pole unit 409A, and the second multi-pole unit 409B are arranged for the purpose of adjusting the direction of the particle beam in respect of the axis of the third electrostatic lens 407 and the entrance window of a beam deflection device 410. The first electrostatic beam deflection unit 409, the first multi-pole unit 409A and the second multi-pole unit 409B may interact like a Wien filter. A further magnetic deflection element 432 is arranged at the entrance to the beam deflection device 410.

The beam deflection device 410 is used as a particle beam deflector, which deflects the particle beam in a specific manner. The beam deflection device 410 comprises a plurality of magnetic sectors, namely a first magnetic sector 411A, a second magnetic sector 411B, a third magnetic sector 411C, a fourth magnetic sector 411D, a fifth magnetic sector 411E, a sixth magnetic sector 411F, and a seventh magnetic sector 411G. The particle beam enters the beam deflection device 410 along the first optical axis OA1 and said particle beam is deflected by the beam deflection device 410 in the direction of a second optical axis OA2. The beam deflection is performed by means of the first magnetic sector 411A, by means of the second magnetic sector 411B and by means of the third magnetic sector 411C by an angle of 30° to 120°. The second optical axis OA2 is oriented at an angle of the same size with respect to the first optical axis OA1. The beam deflection device 410 also deflects the particle beam, which is guided along the second optical axis OA2, in the direction of a third optical axis OA3. The beam deflection is provided by the third magnetic sector 411C, the fourth magnetic sector 411D, and the fifth magnetic sector 411E. In the exemplary embodiment in FIG. 3, the deflection with respect to the second optical axis OA2 and with respect to the third optical axis OA3 is provided by deflecting the particle beam by an angle of 90°. Hence, the third optical axis OA3 extends coaxially with the first optical axis OA1. However, reference is made to the fact that the particle beam device 400 according to the invention described herein is not restricted to deflection angles of 90°. Rather, any suitable deflection angle may be selected by the beam deflection device 410, for example 70° or 110°, such that the first optical axis OA1 does not extend coaxially with the third optical axis OA3. For further details of the beam deflection device 410, reference is made to WO 2002/067286 A2.

After the particle beam has been deflected by the first magnetic sector 411A, the second magnetic sector 411B, and the third magnetic sector 411C, the particle beam is guided along the second optical axis OA2. The particle beam is guided to an electrostatic mirror 414 and travels on its path to the electrostatic mirror 414 along a fourth electrostatic lens 415, a third multi-pole unit 416A in the form of a magnetic deflection unit, a second electrostatic beam deflection unit 416, a third electrostatic beam deflection unit 417, and a fourth multi-pole unit 416B in the form of a magnetic deflection unit. The electrostatic mirror 414 comprises a first mirror electrode 413A, a second mirror electrode 413B, and a third mirror electrode 413C. Electrons of the particle beam which are reflected back at the electrostatic mirror 414 once again travel along the second optical axis OA2 and re-enter the beam deflection device 410. Then, they are deflected to the third optical axis OA3 by the third magnetic sector 411C, the fourth magnetic sector 411D, and the fifth magnetic sector 411E.

The electrons of the particle beam emerge from the beam deflection device 410 and said electrons are guided along the third optical axis OA3 to an object 425 that is intended to be examined and arranged on an object stage 424. On its path to the object 425, the particle beam is guided along a fifth electrostatic lens 418, a beam-guiding tube 420, a fifth multi-pole unit 418A, a sixth multi-pole unit 418B, and an objective lens 421. The fifth electrostatic lens 418 is an electrostatic immersion lens. By means of the fifth electrostatic lens 418, the particle beam is decelerated or accelerated to an electric potential of the beam-guiding tube 420.

By means of the objective lens 421, the particle beam is focused in a focal plane in which the object 425 is arranged. The object 425 is arranged on the movable object stage 424. The movable object stage 424 is arranged in an object chamber 426 of the particle beam device 400. The object stage 424 is embodied to be movable in three directions arranged perpendicular to each other, namely in an x-direction (first stage axis), in a y-direction (second stage axis) and in a z-direction (third stage axis). Moreover, the object stage 424 can be rotated about two rotational axes which are arranged perpendicular to one another, namely a first stage rotation axis and a second stage rotation axis.

The object chamber 426 is under vacuum. For the purpose of generating the vacuum, a pump (not illustrated) is arranged at the object chamber 426. In the exemplary embodiment illustrated in FIG. 3, the object chamber 426 is operated in a first pressure range or in a second pressure range. The first pressure range comprises only pressures of less than or equal to 10⁻³ hPa, and the second pressure range comprises only pressures of greater than 10⁻³ hPa. To ensure said pressure ranges, the object chamber 426 is vacuum-sealed.

The objective lens 421 may be embodied as a combination of a magnetic lens 422 and a sixth electrostatic lens 423. Further, the end of the beam-guiding tube 420 may be an electrode of an electrostatic lens. After emerging from the beam-guiding tube 420, particles of the particle beam device 400 are decelerated to a potential of the object 425. The objective lens 421 is not restricted to a combination of the magnetic lens 422 and the sixth electrostatic lens 423. Rather, the objective lens 421 may assume any suitable form. By way of example, the objective lens 421 may also be embodied as a purely magnetic lens or as a purely electrostatic lens.

The particle beam which is focused onto the object 425 interacts with the object 425. Interaction particles are generated. In particular, secondary electrons are emitted from the object 425 or backscattered electrons are scattered back at the object 425. The secondary electrons or the backscattered electrons are accelerated again and guided into the beam-guiding tube 420 along the third optical axis OA3. In particular, the trajectories of the secondary electrons and the backscattered electrons extend on the route of the beam path of the particle beam in the opposite direction to the particle beam.

The particle beam device 400 comprises a first analysis detector 419 which is arranged between the beam deflection device 410 and the objective lens 421 along the beam path. Secondary electrons traveling in directions oriented at a large angle with respect to the third optical axis OA3 are detected by the first analysis detector 419. Backscattered electrons and secondary electrons which have a small axial distance from the third optical axis OA3 at the location of the first analysis detector 419—i.e. backscattered electrons and secondary electrons which have a small distance from the third optical axis OA3 at the location of the first analysis detector 419—enter the beam deflection device 410 and are deflected to a second analysis detector 428 by the fifth magnetic sector 411E, the sixth magnetic sector 411F and the seventh magnetic sector 411G along a detection beam path 427. By way of example, the deflection angle is 90° or 110°.

The first analysis detector 419 generates detection signals which are largely generated by emitted secondary electrons. The detection signals which are generated by the first analysis detector 419 are guided to a device control unit 123 and used to obtain information about the properties of the interaction region of the focused particle beam with the object 425. In particular, the focused particle beam is scanned over the object 425 using a scanning device 429. After that, an image of the scanned region of the object 425 can be generated by the detection signals, which are generated by the first analysis detector 419, and it can be displayed on a display unit. The display unit is for example a monitor 124 that is arranged at the device control unit 123. Moreover, the device control unit 123 comprises a database 129.

The second analysis detector 428 is also connected to the device control unit 123. Detection signals generated by the second analysis detector 428 are supplied to the device control unit 123 and used to generate an image of the scanned region of the object 425 and to display it on a display unit. The display unit is for example the monitor 124 that is arranged at the device control unit 123.

Arranged at the object chamber 426 is a radiation detector 500, which is used to detect interaction radiation, for example x-ray radiation and/or cathodoluminescence. The radiation detector 500 is connected to the device control unit 123, which comprises the monitor 124. The device control unit 123 processes detection signals generated by the radiation detector 500 and displays them in the form of images on the monitor 124.

Further, the particle beam device 400 has a movable unit 119 which may be a manipulator, a chamber detector and/or a gas injection device.

As mentioned above, the manipulator may be a micromanipulator. The manipulator may be used for lifting a part of the object 425 out of the object 425 and for arranging the part of the object 425 on a TEM sample holder. The micromanipulator may have a first gripper unit and a second gripper unit. Additionally or alternatively, the micromanipulator may comprise at least one optical fiber for providing light to the object 425, for example laser light for preparing the object 425. Moreover, the micromanipulator may comprise an electrical testing probe, a mechanical testing probe or an optical testing probe.

The chamber detector may be a particle detector and/or a radiation detector. For example, the chamber detector may be moved to or away from a specific detection position in the object chamber 426 of the particle beam device 400. Moreover, the chamber detector may comprise an electrical testing probe, a mechanical testing probe or an optical testing probe.

The gas injection device may be a gas needle, an assembly of several gas needles or any other gas injection unit of a gas injection system providing gas to the object 425. For example, the gas injection device may be moved to or away from a specific injection position with respect to the object 425 in the object chamber 426 of the particle beam device 400.

The movable unit 119 is connected to a drive unit 127 and may be moved in an x-direction (namely a first unit direction), in a y-direction (namely a second unit direction) and in a z-direction (namely a third unit direction) using the drive unit 127. All directions are perpendicular to each other. Additionally, the movable unit 119 may be rotated about a first unit axis of rotation and about a second unit axis of rotation arranged perpendicular to the first unit axis of rotation, wherein the drive unit 127 is used for the rotation. The drive unit 127 may be a motor, for example a stepper motor or a piezo motor. It is explicitly mentioned that the drive unit 127 is not restricted to the aforementioned embodiments. Rather, the drive unit 127 may be any drive unit which is suitable for the invention.

Furthermore, the particle beam device 400 comprises a processor 128 into which a program code is loaded for controlling the particle beam device 400 in such a way that a method according to the invention is carried out.

The object stage 114, 424 of the particle beam devices 100, 200 and 400 described above will now be discussed in more detail. The object stage 114, 424 is embodied as a movable object stage, which is illustrated schematically in FIGS. 4 and 5. Reference is made to the fact that the invention is not restricted to the object stage 114, 424 depicted here. Rather, the invention can have any movable object stage that is suitable for the invention.

Arranged on the object stage 114, 424 is the object 125, 425. The object stage 114, 424 has movement elements that ensure a movement of the object stage 114, 424 in such a way that a region of interest on the object 125, 425 can be examined by means of a particle beam. The movement elements are illustrated schematically in FIGS. 4 and 5 and are explained below.

The object stage 114, 424 has a first movement element 600 at a housing 601 of the object chamber 120, 201 or 426, in which the object stage 114, 424 is arranged. The first movement element 600 facilitates a movement of the object stage 114, 424 along the z-axis (third stage axis). Further, provision is made of a second movement element 602. The second movement element 602 facilitates a rotation of the object stage 114, 424 about a first stage rotation axis 603, which is also referred to as a tilt axis. This second movement element 602 serves to tilt the object 125, 425 arranged on the object stage 114, 424 about the first stage rotation axis 603.

Arranged at the second movement element 602, in turn, is a third movement element 604 that is embodied as a guide for a carriage and that ensures that the object stage 114, 424 is movable in the x-direction (first stage axis). The aforementioned carriage is a further movement element, namely a fourth movement element 605. The fourth movement element 605 is embodied in such a way that the object stage 114, 424 is movable in the y-direction (second stage axis). To this end, the fourth movement element 605 has a guide in which a further carriage is guided.

The carriage is embodied, in turn, with a fifth movement element 606 that facilitates a rotation of the object 125, 425 about a second stage rotation axis 607. The second stage rotation axis 607 is oriented perpendicular to the first stage rotation axis 603.

On account of the above-described arrangement, the object stage 114, 424 of the exemplary embodiment discussed here has the following kinematic chain: first movement element 600 (movement along the z-axis)—second movement element 602 (rotation about the first stage rotation axis 603)—third movement element 604 (movement along the x-axis)—fourth movement element 605 (movement along the y-axis)—fifth movement element 606 (rotation about the second stage rotation axis 607).

In a further exemplary embodiment (not illustrated here), provision is made for further movement elements to be arranged at the object stage 114, 424 such that movements along further translational axes and/or about further rotational axes are facilitated.

Each of the aforementioned movement elements is connected to a stepper motor. Thus, the first movement element 600 is connected to a first stepper motor M1 and the former is driven by a driving force that is provided by the first stepper motor M1. The second movement element 602 is connected to a second stepper motor M2, which drives the second movement element 602. The third movement element 604 is connected, in turn, to a third stepper motor M3. The third stepper motor M3 generates a driving force for driving the third movement element 604. The fourth movement element 605 is connected to a fourth stepper motor M4, wherein the fourth stepper motor M4 drives the fourth movement element 605. Further, the fifth movement element 606 is connected to a fifth stepper motor M5. The fifth stepper motor M5 generates a driving force that drives the fifth movement element 606. The aforementioned stepper motors M1 to M5 are controlled by a control unit 608 (see FIG. 5).

FIG. 6 shows a schematic drawing of an embodiment of the device control unit 123 comprising the monitor 124 and the processor 128. The device control unit 123 further comprises a camera unit 130 and a touchless motion sensor 131. The touchless motion sensor 131 may be an infrared touchless motion sensor and/or a touchless motion sensor using ultrasound, high-frequency and/or microwaves. Moreover, the touchless motion sensor 131 may comprise a Doppler radar unit. It is explicitly mentioned that the invention is not restricted to a single camera unit 130 and/or single touchless motion sensor 131. Rather, the invention may use more than one camera unit 130 and/or more than one touchless motion sensor 131. Furthermore, the device control unit 123 comprises a start button 132 and a stop button 133. FIG. 6 also shows a hand 134 of the user. A wireless motion sensor 138 is arranged at the hand 134 of the user. The wireless motion sensor 138 may be a data glove and/or an accelerometer and/or a gravity sensor.

FIG. 7 shows an exemplary embodiment of a method according to the invention for controlling a movement of the movable unit 119 of the particle beam device in the form of the SEM 100, of the combination device 200 or of the particle beam device 400. The method is explained in an exemplary fashion below on the basis of the operation of the SEM 100 and the movable unit 119. What is said about controlling the movement of the movable unit 119 of the SEM 100 mutatis mutandis also applies to the methods for controlling the movable unit 119 of the further particle beam devices 200 and 400 and/or for controlling the movement of the object stages 114, 424 of the particle beam devices 100, 200 and 400 and/or controlling the movement of the aperture unit 108 of the SEM 100.

In method step S1, at least part of a hand 134 of the user or the complete hand 134 of the user (see FIG. 6) is identified using the camera unit 130 and/or the touchless motion sensor 131. The part of the hand 134 of the user may be a single finger or at least two fingers of the user's hand 134.

In method step S2, a start signal is identified. In particular, the start signal may be provided by the part of the hand 134 of the user or the complete hand 134 of the user. For example, the start signal is identified using the camera unit 130 and/or the touchless motion sensor 131. In particular, the start signal may be a start gesture, for example the forefinger of the user's hand 134 pointing in a first specific direction. Additionally or alternatively, the start signal is generated by pressing the start button 132 arranged at the device control unit 123 of the SEM 100. Additionally or alternatively, the start signal may be provided by a part of a further hand or the complete further hand of the user.

In method step S3, the movement of the part of the hand 134 of the user or of the complete hand 134 of the user is tracked using the camera unit 130 and/or the touchless motion sensor 131.

In method step S4, the movement of the part of the hand 134 of the user or the complete hand 134 of the user is transformed into a command for control of the movable unit 119, namely in this embodiment a calculated movement of the movable unit 119 of the SEM 100 using the processor 128. In particular, the step of transforming the movement of the part of the hand 134 of the user or the complete hand 134 of the user into the calculated movement of the movable unit 119 of the SEM 100 comprises a coordinate transformation from the first coordinate system in the form of the coordinate system of the part of the hand 134 of the user or the complete hand 134 of the user into a second coordinate system in the form of a coordinate system of the movable unit 119 of the SEM 100. Furthermore, the step of tracking the movement of the part of the hand 134 of the user or of the complete hand 134 of the user comprises the step of identifying a direction and/or a velocity of the movement of the part of the hand 134 of the user or the complete hand 134 of the user. In particular, the step of tracking the movement of the part of the hand 134 of the user or the complete hand 134 of the user comprises identifying an orientation of the part of the hand 134 of the user or the complete hand 134 in a three-dimensional space.

In method step S5, the movable unit 119 is moved using the drive unit 127. The movement of the movable unit 119 is provided according to the calculated movement. In particular, the movable unit 119 of the SEM 100 may be proportionally moved in a first direction corresponding to a second direction of the movement of the part of the hand 134 of the user or the complete hand 134 of the user with a first velocity proportionally corresponding to a second velocity of the part of the hand 134 of the user or the complete hand 134 of the user.

In method step S6, a stop signal is identified. In particular, the stop signal may be generated by the part of the hand 134 of the user or the complete hand 134 of the user. For example, the stop signal is identified using the camera unit 130 and/or the touchless motion sensor 131. In particular, the stop signal may be a stop gesture, for example the forefinger of the user's hand 134 pointing in a second specific direction. Additionally or alternatively, the stop signal is provided by the part of the further hand or the complete further hand of the user. Additionally or alternatively, the stop signal is generated by pressing the stop button 133 arranged at the device control unit 123 of the SEM 100 or by releasing the start button 132 arranged at the device control unit 123 of the SEM 100.

The invention provides for an accurate movement of the movable unit 119 of the SEM 100 by moving a part of the hand 134 of the user or the complete hand 134 of the user, by tracking this movement of the part of the hand 134 of the user or the complete hand 134 of the user and by transforming this movement of the part of the hand 134 of the user or the complete hand 134 of the user into the proportional movement of the movable unit 119 of the SEM 100. The risk of confusing the axes of direction or axes of rotation of the movement of the movable unit 119 is reduced. Moreover, the invention provides for good control of the velocity and/or the acceleration of the movement of the movable unit 119. This reduces the risk of collision of the movable unit 119 of the SEM 100 with further units of the SEM 100. The user is in a position to control several axes of direction and axes of rotation of the movable unit 119 at once and to provide compensation of the movement of the movable unit 119, which might be necessary as explained above.

FIG. 8 shows a further exemplary embodiment of a method according to the invention for controlling a unit of the particle beam device in the form of the SEM 100, of the combination device 200 or of the particle beam device 400. The method is explained in an exemplary fashion below on the basis of the operation of the SEM 100 and units of the SEM 100 mentioned below. What is said about controlling units of the SEM 100 mutatis mutandis also applies to the methods for controlling units of the further particle beam devices 200 and 400.

In method step S1A, a start signal is identified. In particular, the start signal may be provided by a part of the hand 134 of the user or the complete hand 134 of the user. For example, the start signal is identified using the camera unit 130 and/or the touchless motion sensor 131. In particular, the start signal may be a start gesture, for example the forefinger of the user's hand 134 pointing in a first specific direction. Additionally or alternatively, the start signal is generated by pressing the start button 132 arranged at the device control unit 123 of the SEM 100. Additionally or alternatively, the start signal may be provided by a part of a further hand or the complete further hand of the user.

In method step S2A, a gesture provided by at least one part of the hand 134 of the user or the complete hand 134 of a user (see FIG. 6) is identified using the camera unit 130. The part of the hand 134 of the user may be a single finger or at least two fingers of the user's hand 134. The gesture may be a static gesture.

In method step S3A, a command for a control of a unit to be controlled of the SEM 100 is selected by means of the identified gesture. For example, the gesture is stored in the database 129 of the device control unit 123 and is associated to a specific command for controlling a specific unit. This specific command is selected and, for example, loaded from the database 129 into a control unit of the specific unit. For example, the command is loaded in the processor 128 of the device control unit 123.

In method step S4A, according to the command, the processor 128 may provide control signals to the drive unit 127 which drives the movable unit 119, to the control unit 608 of the object stage 114 for moving the object stage 114, to the adjustment mechanism 126 for adjusting the first aperture unit 108, to the high voltage control unit 135 for adjusting the acceleration voltage of the electrons of the primary electron beam, to the current control unit 136 for adjusting a current of the objective lens 107, to the condenser control unit 139 for controlling the first condenser lens 105 and the second condenser lens 106, to the scan control unit 140 for controlling the scanning device 115, to the stigmator control unit 141 for controlling the stigmator 137 and/or to the device control unit 123 for choosing detection of particles and/or radiation.

In method step S5A, the specific unit is controlled according to the control signals provided to the specific and associated control unit as above mentioned. In method step S6A, a stop signal is identified. In particular, the stop signal may be generated by the part of the hand 134 of the user or the complete hand 134 of the user. For example, the stop signal is identified using the camera unit 130 and/or the touchless motion sensor 131. In particular, the stop signal may be a stop gesture, for example the forefinger of the user's hand 134 pointing in a second specific direction. Additionally or alternatively, the stop signal is provided by the part of the further hand or the complete further hand of the user. Additionally or alternatively, the stop signal is generated by pressing the stop button 133 arranged at the device control unit 123 of the SEM 100 or by releasing the start button 132 arranged at the device control unit 123 of the SEM 100.

FIG. 8 is now also used to explain the method on the basis of a further exemplary operation of the particle beam devices 200.

In method step S1A, a start signal is identified. In particular, the start signal may be provided by a part of the hand 134 of the user or the complete hand 134 of the user. For example, the start signal is identified using the camera unit 130 and/or the touchless motion sensor 131. In particular, the start signal may be a start gesture, for example the forefinger of the user's hand 134 pointing in a first specific direction. Additionally or alternatively, the start signal is generated by pressing the start button 132 arranged at the device control unit 123 of the SEM 100. Additionally or alternatively, the start signal may be provided by a part of a further hand or the complete further hand of the user.

In method step S2A, a gesture provided by at least a part of the hand 134 of the user or the complete hand 134 of the user (see FIG. 6) is identified using the camera unit 130. The part of the hand 134 of the user may be a single finger or at least two fingers of the user's hand 134. The gesture may be a static gesture. In method step S3A, a command for a control of a unit to be controlled of the particle beam device 200 is selected by means of the identified gesture. For example, the gesture is stored in the database 129 of the device control unit 123 and is associated to a specific command for controlling a specific unit. This specific command is selected and, for example, loaded from the database 129 into an associated control unit of the specific unit. For example, the command is loaded in the processor 128 of the device control unit 123.

In method step S4A, according to the command, the processor 128 may provide control signals to the vacuum control unit 204 for controlling the vacuum system 202 and the valve 203 or to the device control unit 123 to select the primary electron beam and/or the ion beam to be guided to the object 125. In method step S5A, the aforementioned specific unit is controlled according to the control signals provided to the associated specific control unit.

In method step S6A, a stop signal is identified. In particular, the stop signal may be generated by the part of the hand 134 of the user or the complete hand 134 of the user. For example, the stop signal is identified using the camera unit 130 and/or the touchless motion sensor 131. In particular, the stop signal may be a stop gesture, for example the forefinger of the user's hand 134 pointing in a second specific direction. Additionally or alternatively, the stop signal is provided by the part of the further hand or the complete further hand of the user. Additionally or alternatively, the stop signal is generated by pressing the stop button 133 arranged at the device control unit 123 of the SEM 100 or by releasing the start button 132 arranged at the device control unit 123 of the SEM 100.

Various embodiments discussed herein may be combined with each other in appropriate combinations in connection with the system described herein. Additionally, in some instances, the order of steps in the flow diagrams, flowcharts and/or described flow processing may be modified where appropriate. Further, various aspects of the system described herein may be implemented using software, hardware, a combination of software and hardware and/or other computer-implemented modules or devices having the described features and performing the described functions. The system may further include a display and/or other computer components for providing a suitable interface with a user and/or with other computers.

Software implementations of aspects of the system described herein may include executable code that is stored in a computer-readable medium and executed by one or more processors. The computer-readable medium may include volatile memory and/or non-volatile memory, and may include, for example, a computer hard drive, ROM, RAM, flash memory, a cloud storage, portable computer storage media such as a CD-ROM, a DVD-ROM, an SO card, a flash drive or other drive with, for example, a universal serial bus (USB) interface, and/or any other appropriate tangible or non-transitory computer-readable medium or computer memory on which executable code may be stored and executed by a processor. The system described herein may be used in connection with any appropriate operating system.

The features of the invention disclosed in the present description, in the drawings and in the claims may be essential for the realization of the invention in the various embodiments thereof, both individually and in arbitrary combinations. The invention is not restricted to the described embodiments. It may be varied within the scope of the claims, taking into account the knowledge of the relevant person skilled in the art.

### LIST OF REFERENCE SIGNS

100 SEM
101 electron source
102 extraction electrode
103 anode
104 beam-guiding tube
105 first condenser lens
106 second condenser lens
107 first objective lens
108 first aperture unit
108A first aperture
109 second aperture unit
110 pole pieces
111 coil
112 single electrode
113 tube electrode
114 object stage
115 scanning device
116 first detector
116A opposing field grating
117 second detector
118 second aperture
119 movable unit
120 object chamber
121 third detector
123 device control unit
124 monitor
125 object
126 adjustment mechanism
127 drive unit
128 processor
129 database
130 camera unit
131 touchless motion sensor
132 start button
133 stop button
134 hand of a user
135 high voltage control unit
136 current control unit
137 stigmator
138 wireless motion sensor
139 condenser control unit
140 scan control unit
141 stigmator control unit
200 combination device
201 object chamber
202 vacuum system
203 valve
204 vacuum control unit
300 ion beam device
301 ion beam generator
302 extraction electrode in the ion beam device
303 condenser lens
304 second objective lens
306 adjustable or selectable aperture unit
307 first electrode arrangement
308 second electrode arrangement
400 particle beam device with corrector unit
401 particle beam column
402 electron source
403 extraction electrode
404 anode
405 first electrostatic lens
406 second electrostatic lens
407 third electrostatic lens
408 magnetic deflection unit
409 first electrostatic beam deflection unit
409A first multi-pole unit
409B second multi-pole unit
410 beam deflection device
411A first magnetic sector
411B second magnetic sector
411C third magnetic sector
411D fourth magnetic sector
411E fifth magnetic sector
411F sixth magnetic sector
411G seventh magnetic sector
413A first mirror electrode
413B second mirror electrode
413C third mirror electrode
414 electrostatic mirror
415 fourth electrostatic lens
416 second electrostatic beam deflection unit
416A third multi-pole unit
416B fourth multi-pole unit
417 third electrostatic beam deflection unit
418 fifth electrostatic lens
418A fifth multi-pole unit
418B sixth multi-pole unit
419 first analysis detector
420 beam-guiding tube
421 objective lens
422 magnetic lens
423 sixth electrostatic lens
424 object stage
425 object
426 object chamber
427 detection beam path
428 second analysis detector
429 scanning device
432 further magnetic deflection element
500 radiation detector
600 first movement element
601 housing
602 second movement element
603 first stage rotation axis
604 third movement element
605 fourth movement element
606 fifth movement element
607 second stage rotation axis
608 control unit
709 first beam axis
710 second beam axis
M1 first stepper motor
M2 second stepper motor
M3 third stepper motor
M4 fourth stepper motor
M5 fifth stepper motor
OA optical axis
OA1 first optical axis
OA2 second optical axis
OA3 third optical axis
S1 to S6 method steps
S1A to S6A method steps

1. Method for controlling a unit (105, 106, 107, 108, 114, 119, 123, 135, 136, 137, 140, 204, 424) of a particle beam device (100, 200, 400) for imaging, analyzing and/or processing an object (125, 425), comprising:
identifying at least one part of at least one hand (134) of a user or at least one complete hand (134) of a user by means of an identification unit (130, 131), wherein the identification unit (130, 131) is at least one of: (i) a first camera unit (130), (ii) a first touchless motion sensor (131) or (iii) a first wireless motion sensor;
tracking an absolute movement and/or a relative movement of the at least one part of the at least one hand (134) of the user or the at least one complete hand (134) of the user by means of a tracking unit (130, 131), wherein the tracking unit (130, 131) is at least one of: (i) a second camera unit (130), (ii) a second touchless motion sensor (131) or (iii) a second wireless motion sensor;
transforming the movement of the at least one part of the at least one hand (134) of the user or the at least one complete hand (134) of the user into a command for a control of the unit (105, 106, 107, 108, 114, 119, 123, 135, 136, 137, 140, 204, 424) of the particle beam device (100, 200, 400) by means of a transformation unit (128); and
providing the control of the unit (105, 106, 107, 108, 114, 119, 123, 135, 136, 137, 140, 204, 424) of the particle beam device (100, 200, 400) by means of the command, wherein the command is used as an input in a control unit (123, 127, 135, 136, 138 bis 141, 608, M1 to M5) for controlling the unit (105, 106, 107, 108, 114, 119, 123, 135, 136, 137, 140, 204, 424) of the particle beam device (100, 200, 400).

2-28. (canceled)
